(19) United States
(12) Patent Application Publication
(10) Pub. No.: US 2007/0206414 A1
(43) Pub. Date: Sep. 6, 2007

(54) METHOD OF FABRICATING A MULTI-BIT MEMORY CELL

(76) Inventor: Cheol Sang Kwak, Seoul (KR)

Correspondence Address: SHERR & NOURSE, PLLC, 620 HERNDON PARKWAY, SUITE 200, HERNDON, VA, 20170, US

(21) Appl. No.: 11/608,089

(22) Filed: Dec. 7, 2006

(30) Foreign Application Priority Data
Dec. 9, 2005 (KR) 10-2005-0120590

(51) Int. Cl. G11C 16/04; G11C 11/34

(52) U.S. Cl. 365/185.1

(57) ABSTRACT

The method of fabricating a multi-bit flash memory cell begins with forming an ion implantation mask exposing a portion of a channel region in a semiconductor substrate. Ions are implanted into the exposed region thereby partially coding the threshold voltage to create one ion implanted channel region with a first threshold voltage, and a second region without implanted ions having a second threshold voltage. A tunnel dielectric layer is formed over the channel region and floating and control gates are formed over the tunnel dielectric layer.

### BACKGROUND

The disclosure relates to a semiconductor device, and more particularly to a method of fabricating a multi-bit flash memory cell which can store multi-bit information in a single memory cell.

Flash memory cells usually store a single bit in a single memory cell. However, efforts have been made to store two or more bits within a single memory cell. The goal is to effectively increase the degree of integration and storage capacity of a flash memory device.

FIGS. 1 and 2 are cross-sectional views schematically illustrating a method of fabricating a flash memory cell. FIG. 3 is a schematic view illustrating a 1-bit operation of the flash memory cell.

Referring to FIG. 1, device isolation wells 15 are formed on a semiconductor substrate 10, and a tunnel dielectric film 20 is formed using a silicon oxide or the like over the semiconductor substrate 10.

Referring to FIG. 2, floating and control gates 30 and 40 are formed over the tunnel dielectric film 20 by deposition, photolithography and selective etching processes. An Oxide Nitride Oxide (ONO) layer may serve as a coupling dielectric layer between the floating gate 30 and control gate 40.

A drain, connected to a bit line, is also connected to a common source by a channel region 11 which sits below the floating gate 30 and control gate 40. The channel region 11 connects the drain and source through the portion of the substrate 10 immediately below the stacked floating and control gates 30 and 40. This flash memory cell configuration performs 1-bit operations.

Referring to FIGS. 2 and 3, the flash memory cell performs 1-bit operations by changing the threshold voltage (Vt) in the channel region 11, which is the portion of the semiconductor substrate 10 immediately below the control gate 40.

The floating gate 30 is used to store a bit. When electrons are implanted into the floating gate 30, it is set into a programmed state, and the channel region assumes a first value of threshold voltage Vt. When gate electrons are removed from the floating gate 30, it is erased or set to zero, and channel region 11 assumes a second value for Vt. Accordingly, Vt assumes values in a program and erase states which are distinguishable. By assigning binary values to the states, one bit may be stored.

In this way, a flash memory cell serves as a non-volatile memory cell capable of storing one bit per cell. However, there has been a continuing need for securing more data storage per cell to increase data storage per unit area, thereby reducing the production cost per stored bit.

### SUMMARY

Embodiments illustrate a method of fabricating a flash memory cell which can store at least 2 bits in a single memory cell.

In accordance with embodiments, a method of fabricating a multi-bit flash memory cell includes: forming an opening in an ion implantation over a first region corresponding to a portion of a channel region in a semiconductor substrate; selectively implanting ions into the region opened by the ion implantation mask and partially coding a threshold voltage of the channel region to split the channel region into a first threshold voltage region to which the ions are not implanted and a second threshold voltage region to which the ions are implanted; forming a tunnel dielectric layer over the channel region; and forming floating and control gates over the tunnel dielectric layer. In embodiments, the first region may be set as a region corresponding to about a half portion of the channel region to form the ion implantation mask.

Embodiments relate to a method of fabricating a multi-bit flash memory cell, which includes the steps of: forming a tunnel dielectric layer over a semiconductor substrate; forming floating and control gates over the tunnel dielectric layer; forming an ion implantation mask opening a first region corresponding to a portion of a channel region within the semiconductor substrate below the floating gate; and selectively implanting ions into the region opened by the ion implantation mask and partially coding a threshold voltage of the channel region to split the channel region into a first threshold voltage region to which the ions are not implanted and a second threshold voltage region to which the ions are implanted. In embodiments, the ion implantation mask may be formed over the control gate.

Embodiments relate to a multi-bit flash memory cell which comprises; a semiconductor substrate; a tunnel dielectric layer formed over the semiconductor substrate; floating and control gates formed over the tunnel dielectric layer; and a channel region formed in the tunnel dielectric layer below the floating gate. The channel region includes a first region and a second region. The first region has a first threshold voltage (Vt) which is the threshold voltage of the channel region. Furthermore, the second region has a second threshold voltage which is different from the first threshold voltage by ion implantation. In embodiments, the first region is set as a region corresponding to about a half portion of the channel region to form an ion implantation mask.

In embodiments, a multi-bit flash memory cell comprises: a semiconductor substrate; a tunnel dielectric layer formed over the semiconductor substrate; floating and control gates formed over the tunnel dielectric layer; and a channel region formed in the tunnel dielectric layer below the floating gate. The channel region includes a first region and a second region. The first region has a first threshold voltage (Vt). Furthermore, the second region has a second threshold voltage which is different from the first threshold voltage by ion implantation. In embodiments, the first region is set as a region corresponding to about a half portion of the channel region to form an ion implantation mask.

Embodiments relate to a method of fabricating a multi-bit flash memory cell which can store at least 2-bit multi-bit information in a single memory cell by split the threshold voltage distribution of a channel region into two through an ion implantation coding.

### BRIEF DESCRIPTION OF THE DRAWINGS

FIGS. 1 and 2 are cross-sectional views schematically illustrating a method of fabricating a flash memory cell.

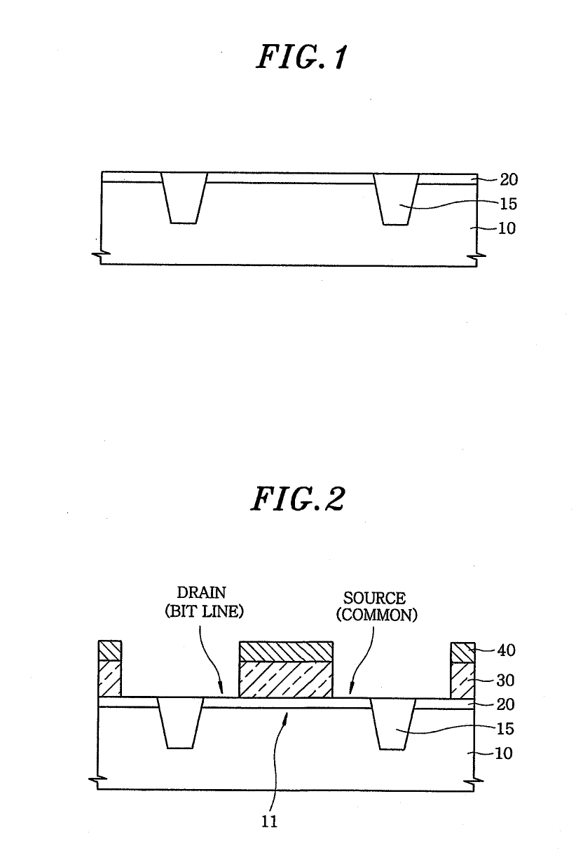

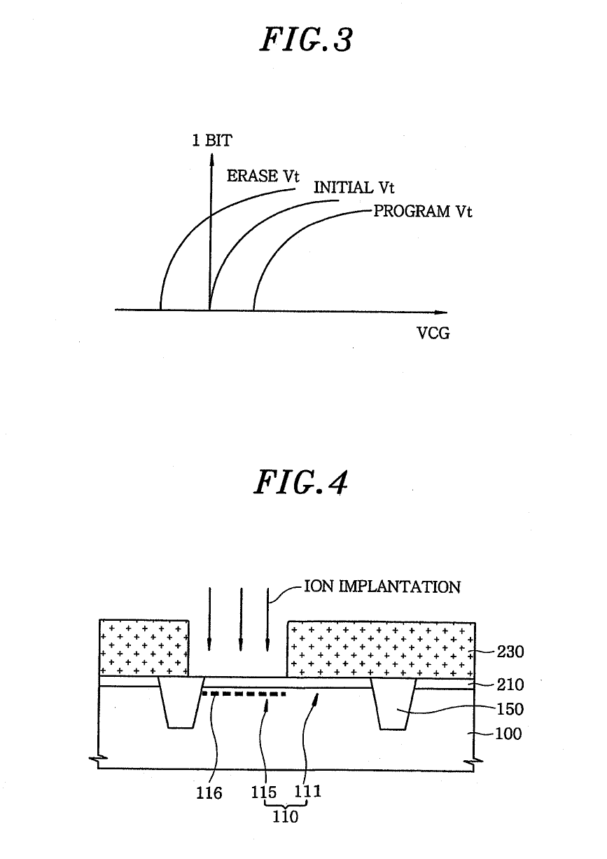

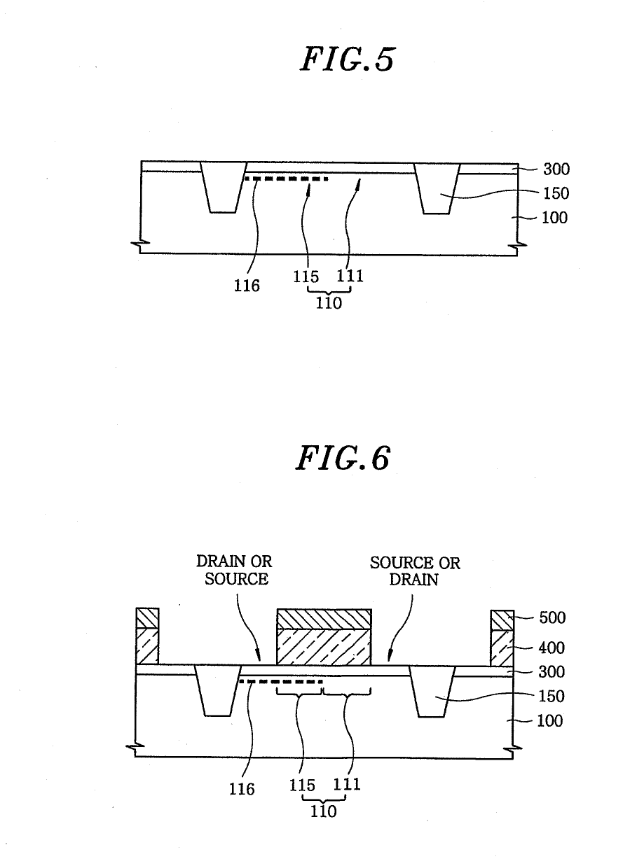

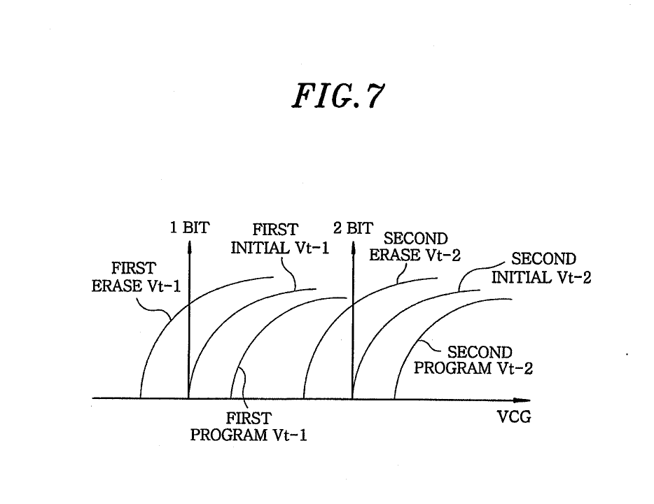

Example FIG. 3 is a schematic view illustrating 1-bit operation of a flash memory cell, in accordance with embodiments.

Example FIGS. 4 to 6 are cross-sectional views schematically illustrating a method of fabricating a multi-bit flash memory cell using ion implantation coding, in accordance with embodiments.

Example FIG. 7 is a schematic view illustrating 2-bit operation of a flash memory cell, in accordance with embodiments.

### DETAILED DESCRIPTION

Embodiments relate to a method of manufacturing a multi-bit flash memory cell provides that the initial Vt of a channel region is differentiated across two channel sub-regions by selectively implanting ions into only about half of the channel region.

FIGS. 4 to 6 are cross-sectional views schematically illustrating a method of fabricating a multi-bit flash memory cell using ion implantation coding according to embodiments. FIG. 7 is a schematic view illustrating a 2-bit operation of a flash memory cell according to embodiments.

Referring to FIG. 4, device isolation wells 150 are first formed in a shallow trench isolation process (STI) or the like over a semiconductor substrate 100. A buffer layer 210 including an oxide film, which will be used as an ion implantation pad, is formed over the semiconductor substrate 100.

Thereafter, an ion implantation mask 230 selectively exposing a portion 115 corresponding to about half of a channel region 110 is formed as a photoresist pattern. A Vt coding layer 116 is formed in the half portion 115 of the channel region 110 by selectively implanting impurity ions into the semiconductor substrate 100 exposed by the photoresist pattern 230.

Accordingly, different values of Vt are implemented in second and first portions 115 and 111 to which the Vt coding layer 116 of the channel region 110 is implanted and not implanted, respectively. That is, first and second initial values of Vt (Vt-1, Vt-2) are implemented in the first and second portions 111 and 115 of the channel region 110, respectively, so that the Vt of the channel region 110 is differentiated across the first and second portions 111 and 115. In other words, the first and second portions 111 and 115 may be understood as first and second threshold voltage (Vt-1, Vt-2) regions 111 and 115, respectively. Thus, the ion implantation process for the Vt coding layer 116 may be understood as a Vt coding process for differentiating the Vt of the channel region 110 across the two sub-regions.

Referring to FIG. 5, the ion implantation mask 230 and the buffer layer 210 are removed, and a tunnel dielectric layer 300 such as a silicon oxide film is formed over the semiconductor substrate 100.

Referring to FIG. 6, floating and control gates 400 and 500 are formed over the tunnel dielectric film 300 by deposition, photolithography and selective etching processes. An interlayer insulation layer such as a coupling dielectric layer between the floating and control gates 400 and 500 may be employed as an ONO layer.

A drain connected to a bit line and a source common between cells may be connected electrically to each other by the channel region 11 therebetween in a portion of the substrate 100 below the floating and control gates 400 and 500. If either one is set as the source, the other is set as the drain, depending on the desired operation of a cell.

This flash memory cell can perform at least 2-bit operation because the Vt of the channel region 110 is differentiated across the two portions. The cell operates with left and right pinch-off voltages so that storing left and right data can be implemented simultaneously, thereby enabling a four state operation per cell.

The ion implantation coding process may also be performed after the control gate 500 has been formed. The ion implantation mask 230 exposes about half of the channel region 110 as shown in FIG. 4, and ions are selectively implanted.

Referring to FIGS. 6 and 7, the first and second initial values of Vt (Vt-1, Vt-2) are respectively implemented in the first and second threshold voltage regions 111 and 115. Accordingly, a first erase Vt-1 and a first program Vt-1 can be implemented, and a second erase Vt-1 and a second program Vt-2 can be implemented. Since four information storage states can be implemented depending on the voltage applied to the control gate 500, storing and reading two bits is possible.

Accordingly, the degree of integration in flash memory can be enhanced, and the chip size may be reduced by half compared with a one bit per cell memory product with the same overall capacity, in accordance with embodiments.

Two bits or more can be stored within the structure of a single cell using the same area of flash memory cells. That is, a multi-bit flash memory cell can be made by ion implantation coding in a channel region. Accordingly, memory device integration can be increased by a factor of two or more.

The above disclosure has described a multi-bit flash memory cell and fabricating method thereof in which the memory cell has the first region having first threshold voltage Vt-1, which is equal to threshold voltage of the original channel region, to which the ions are not implanted and the second region having the second threshold voltage Vt-2, which is different from the first threshold voltage Vt-1, to which the ions are implanted. Alternatively, the first and the second regions may have a first and a second threshold voltages Vt-1 and Vt-2, each of which is different from the threshold voltage Vt of the original channel region, by implanting different ion concentrations in the first and the second regions.

It will be obvious and apparent to those skilled in the art that various modifications and variations can be made in the embodiments disclosed. Thus, it is intended that the disclosed embodiments covers the obvious and apparent modifications and variations, provided that they are within the scope of the appended claims and their equivalents.

What is claimed is:

1. A method comprising:
implanting ions in a first section of a channel region of a semiconductor substrate, while shielding ion implantation in a second section of the channel region of a semiconductor substrate;
forming a tunnel dielectric layer over the channel region; and
forming a floating gate and a control gate over the tunnel dielectric layer.

2. The method of claim 1, wherein the method fabricates a multi-bit flash memory cell.

3. The method of claim 1, comprising forming an ion implantation mask having an opening over the first section of the channel region.

4. The method of claim 1, wherein:
the first section of the channel region has a first threshold voltage;
the second section of the channel region has a second threshold voltage; and
the first threshold voltage is different than the second threshold voltage.

5. The method of claim 4, wherein the first threshold voltage is higher than the second threshold voltage.

6. The method of claim 1, wherein the first section and the second section are approximately the same size.

7. The method of claim 1, wherein the first section has a higher concentration of implanted ions than the second section.

8. A method of fabricating a multi-bit flash memory cell, comprising:
forming a tunnel dielectric layer over a semiconductor substrate;
forming a floating gate and a control gate over the tunnel dielectric layer;
forming an ion implantation mask exposing a first region corresponding to a portion of a channel region in the semiconductor substrate below the floating gate; and
selectively implanting ions into the region exposed by the ion implantation mask to split the channel region into a first threshold voltage region to which the ions are not implanted and a second threshold voltage region to which the ions are implanted,

9. The method of claim 8, wherein said selectively implanting ions comprises coding the threshold voltage of the channel region by forming said first threshold voltage region and said second threshold voltage region.

10. The method of claim 1, wherein the ion implantation mask is formed over the control gate.

11. An apparatus comprising:
a semiconductor substrate;
a tunnel dielectric layer formed over the semiconductor substrate;
a floating gate and a control gate formed over the tunnel dielectric layer; and
a channel region formed in the tunnel dielectric layer below the floating gate, wherein the channel region includes a first region and a second region, the first region having a first threshold voltage (Vt) which is the threshold voltage of the channel region, and the second region having a second threshold voltage different from the first threshold voltage.

12. The apparatus of claim 11, wherein the apparatus is a multi-bit flash memory cell.

13. The apparatus of claim 11, wherein said second region of said channel region has a relatively higher concentration of implanted ions than said first region.

14. The apparatus of claim 11, wherein said second region included in said channel region comprises about half of the channel region.

15. An apparatus comprising:
a channel region of a semiconductor substrate comprising a first section and a second section, wherein the first section has a higher concentration of implanted ions than the second section;
forming a tunnel dielectric layer over the channel region; and
forming a floating gate and a control gate over the tunnel dielectric layer.

16. The apparatus of claim 15, wherein the apparatus is a multi-bit flash memory cell.

17. The apparatus of claim 15, wherein:
the first section of the channel region has a first threshold voltage;
the second section of the channel region has a second threshold voltage; and
the first threshold voltage is different than the second threshold voltage.

18. The apparatus of claim 17, wherein the first threshold voltage is higher than the second threshold voltage.

19. The apparatus of claim 15, wherein the first section and the second section are approximately the same size.
